(19) United States
(12) Patent Application Publication
(10) Pub. No.: US 2026/0244093 A1
(43) Pub. Date: Aug. 20, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Soobin LIM, Suwon-si (KR); Ahra CHO, Suwon-si (KR); Sumin JANG, Suwon-si (KR); Joonhee HAN, Suwon-si (KR); Yunju CHAE, Suwon-si (KR); Jimin KIM, Suwon-si (KR); Hyun LEE, Suwon-si (KR); Kyungmog KIM, Suwon-si (KR); Chaeeun LEE, Suwon-si (KR)

(21) Appl. No.: 19/538,598

(22) Filed: Feb. 12, 2026

(30) Foreign Application Priority Data
Feb. 17, 2025 (KR) 10-2025-0020302
Feb. 3, 2026 (KR) 10-2026-0021416

(51) Int. Cl. G03F 7/004; C07F 7/22; G03F 7/00; G03F 7/20; H10P 50/00; H10P 76/20

(52) U.S. Cl. CPC G03F 7/0042; C07F 7/2224; H10P 76/204; G03F 7/2004; G03F 7/70033; H10P 50/71; H10P 50/73

(57) ABSTRACT

The present disclosure relates to a semiconductor photoresist composition including an organometallic compound represented by Chemical Formula 1 and a solvent and a method of forming patterns using the same. Chemical Formula 1 is defined as described in the specification. The method of forming patterns according to some example embodiments includes forming an etching-objective layer on a substrate, coating the semiconductor photoresist composition on the etching-objective layer to form a photoresist film, patterning the photoresist film to form a photoresist pattern, and etching the etching-objective layer using the photoresist pattern as an etching mask.

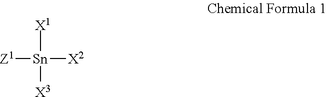

### CROSS-REFERENCE TO RELATED APPLICATION

The present application claims priority to and the benefit of Korean Patent Application No. 10-2025-0020302, filed on Feb. 17, 2025 and Korean Patent application No. 10-2026-0021416, filed on Feb. 3, 2026, the entire disclosure of which is incorporated herein by reference.

### BACKGROUND

### 1. Field

Embodiments of the present disclosure provide a semiconductor photoresist composition and a method of forming patterns using the same.

### 2. Description of the Related Art

EUV (extreme ultraviolet) lithography is paid attention to as one technology for manufacturing a next generation semiconductor device. The EUV lithography is a pattern-forming technology using an EUV ray having a wavelength of 13.5 nm as an exposure light source. According to the EUV lithography, an extremely fine pattern (e.g., less than or equal to 20 nm) may be formed in an exposure process during a manufacture of a semiconductor device.

The extreme ultraviolet (EUV) lithography is realized through development of compatible photoresists which can be performed at a spatial resolution of less than or equal to 16 nm. Currently, efforts to satisfy insufficient specifications of traditional chemically amplified (CA) photoresists such as a resolution, a photospeed, and feature roughness (or also referred to as a line edge roughness or LER) for the next generation device are being made.

An intrinsic image blurring due to an acid catalyzed reaction in these polymer-type photoresists limits a resolution in small feature sizes, which has been present in electron beam (e-beam) lithography for a long time. The chemically amplified (CA) photoresists are designed for high sensitivity, but because their typical elemental makeups reduce light absorbance of the photoresists at a wavelength of 13.5 nm and thus decrease their sensitivity, the chemically amplified (CA) photoresists may partially have more difficulties under an EUV exposure.

In one or more embodiments, the CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a high-performance photoresist is useful in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition is mainly used for negative tone patterning having resistance against removal by a developer composition due to chemical modification through nonchemical amplification mechanism. The inorganic composition contains an inorganic element having a higher EUV absorption rate than hydrocarbon and thus may secure sensitivity through the nonchemical amplification mechanism and in addition, is less sensitive about a stochastic effect and thus has low line edge roughness and the small number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. More recently, when cationic hafnium metal oxide sulfate (HfSOx) materials along with a peroxo complexing agent has been used to image a 15 nm half-pitch (HP) through projection EUV exposure, impressive performance has been obtained. This system exhibits the highest performance of a non-CA photoresist and has a practicable photospeed near to a requirement for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of 25 wt % and/or the like.

Recently, active research has been conducted on molecules including tin that have excellent absorption of extreme ultraviolet rays. As for an organotin polymer among them, alkyl ligands are dissociated by light absorption and/or secondary electrons produced thereby, and are crosslinked with adjacent chains through oxo bonds and thus enable the negative tone patterning which may not be removed by an organic developer. This organotin polymer exhibits greatly improved sensitivity as well as maintains a resolution and line edge roughness, but the patterning characteristics should be additionally improved for commercial availability.

### SUMMARY

Embodiments provide a semiconductor photoresist composition that has excellent sensitivity and improved pattern stability by reducing or minimizing an influence of variables during pattern formation.

Another embodiment provides a method of forming patterns using the semiconductor photoresist composition.

A semiconductor photoresist composition according to some example embodiments includes an organometallic compound represented by Chemical Formula 1 and a solvent:

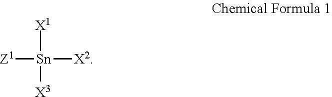

In Chemical Formula 1,
Z¹ is a group containing at least one boron, and
X¹ to X³ are each independently alkoxy and/or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an acyloxy group and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and/or arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

The semiconductor photoresist composition according to some example embodiments has excellent sensitivity, storage stability, and coatability, and thus enables precise control of small-sized patterns and implementation of excellent resolution.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1A to 1E are cross-sectional views that show a method of forming patterns using a semiconductor photoresist composition according to some example embodiments.

### DETAILED DESCRIPTION

Hereinafter, referring to the drawings, embodiments are described in more detail. In the following description of the present disclosure, the certain functions and/or constructions may not be described for purposes of clarity.

In order to clearly illustrate the embodiments of the present disclosure, the description and relationships are not provided, and throughout the disclosure, the same or similar configuration elements are designated by the same reference numerals. Also, because the size and thickness of each configuration shown in the drawings may be arbitrarily shown for better understanding and ease of description, the present disclosure is not necessarily limited thereto.

In the drawings, the thickness of layers, films, panels, regions, and/or the like, may be enlarged for clarity. In the drawings, the thickness of a part of layers or regions, and/or the like, may be exaggerated for convenience of explanation. It will be understood that if (e.g., when) an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a carboxyl group, a thiol group, a cyano group, a nitro group, —NRR′ (wherein, R and R′ are each independently hydrogen, a substituted or unsubstituted C1 to C30 saturation or unsaturated aliphatic hydrocarbon group, a substituted or unsubstituted C3 to C30 saturation or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturation or unsaturated aliphatic hydrocarbon group, a substituted or unsubstituted C3 to C30 saturation or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. As used herein, “unsubstituted” refers to non-replacement of a hydrogen atom by another substituent and remaining of the hydrogen atom.

As used herein, if (e.g., when) a definition is not otherwise provided, an “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, a “cycloalkyl group” refers to a monovalent cyclic aliphatic hydrocarbon group.

The cycloalkyl group may be a C3 to C8 cycloalkyl group, for example, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but is not limited thereto.

As used herein, an “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms).

As used herein, a “heteroaryl group” may refer to aryl group including at least one heteroatom selected from N, O, S, P, and Si. Two or more heteroaryl groups are linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, unless otherwise defined, an “alkenyl group” refers to an aliphatic unsaturated alkenyl group including at least one double bond as a linear or branched aliphatic hydrocarbon group.

As used herein, unless otherwise defined, an “alkynyl group” refers to an aliphatic unsaturated alkynyl group including at least one triple bond as a linear or branched aliphatic hydrocarbon group.

Hereinafter, a semiconductor photoresist composition according to some example embodiments is described.

A semiconductor photoresist composition according to some example embodiments includes an organometallic compound represented by Chemical Formula 1 and a solvent:

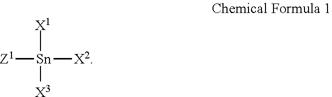

In Chemical Formula 1,
Z¹ is a group containing at least one boron,
X¹ to X³ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, alkoxy and/or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an acyloxy group and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof),
at least one of X¹, X², or X³ is selected from alkoxy and/or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an acyloxy group and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido and/or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio and arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

A method of forming patterns by using a semiconductor photoresist composition including an organometallic compound includes coating the photoresist composition on an etching-objective layer, so that the organometallic compound or its cluster molecules in the photoresist composition may be coated on the etching-objective layer, and then, proceeding with a first baking process, an exposure process, a second baking process, and a development process to remove an organic material in the photoresist composition and thus to pattern a metal oxide.

Herein, the patterning of the metal oxide is affected by various suitable variables, such as a temperature, a solvent, a concentration, a catalyst, an atmosphere, and/or the like, and, for example, the smaller pattern size, the relatively larger effect. Because a pattern formed by a photoresist composition including an organometallic compound has a very small size in a range from several nm to several tens of nm, the metal oxide-patterning may be more affected by the process conditions than other photoresists.

For example, concentration of nitrogen oxide (NOx) in the atmosphere affects the pattern formation by a photoresist composition including an organometallic compound. NOx is a highly reactive substance that exists in the atmosphere and may react with moisture, sunlight, and/or the like in the atmosphere to cause phenomena such as smog and/or the like, wherein if (e.g., when) the concentration of NOx exceeds a set or predetermined level, there is a problem that a pattern width and/or the like, which are checked after the development, differ from target values.

Accordingly, in embodiments of the present disclosure, the organometallic compound as described above includes a boron atom, so that the boron atom may react with a radical derived from nitrogen oxide, thereby suppressing or reducing an unnecessary radical reaction. For example, if (e.g., when) forming a pattern using a semiconductor photoresist composition according to some example embodiments, by suppressing or reducing the reaction with nitrogen oxides in the atmosphere in the exposed region during the exposure process and suppressing or reducing the reaction with radicals that unnecessarily diffuse to the unexposed region, defects or residues occurring in the pattern may be reduced, thereby improving the pattern profile, such as increasing the uniformity of the pattern.

In Chemical Formula 1, Z¹ may be a group represented by Chemical Formula 2:

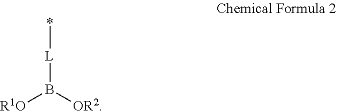

In Chemical Formula 2,
L is a single bond (e.g., a single covalent bond), or a substituted or unsubstituted C1 to C10 alkylene group, R¹ and R² are each independently hydrogen, deuterium, halogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C20 aryl group, or R¹ and R² are optionally linked to form a ring, * is a linking point with Sn of Chemical Formula 1.

In Chemical Formula 2, R¹ and R² may each independently be hydrogen, a substituted or unsubstituted C1 to C20 alkyl group, or a substituted or unsubstituted C2 to C20 alkenyl group, or R¹ and R² are optionally linked to form a ring, and for example R¹ and R² may each independently be hydrogen, a substituted or unsubstituted C1 to C10 alkyl group, or a substituted or unsubstituted C2 to C10 alkenyl group, or R¹ and R² may be optionally linked to form a ring.

If (e.g., when) R¹ and R² of Chemical Formula 2 are linked to form a ring, R¹ and R² may be optionally linked to form a substituted or unsubstituted C2 to C20 heterocycle, for example, R¹ and R² may be optionally connected to form a substituted or unsubstituted C2 to C10 heterocycle, and for example, Chemical Formula 2 may be represented by Chemical Formula 2-1:

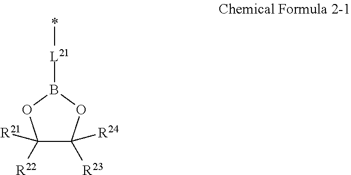

In Chemical Formula 2-1, L²¹ is a single bond (e.g., a single covalent bond), or a substituted or unsubstituted C1 to C10 alkylene group, R²¹ to R²⁴ are each independently hydrogen, deuterium, halogen, a substituted or unsubstituted C1 to C10 alkyl group, or a combination thereof, and * is a linking point with Sn of Chemical Formula 1.

In some example embodiments, in Chemical Formula 1, in the definition of X¹ to X³, R^{b} may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
R^{c}, R^{d}, R^{e}, R^{f}, R^{g}, R^{h}, Rⁱ, R^{j}, R^{k}, and R^{l} may each independently be hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

At least one of X¹, X², or X³ in Chemical Formula 1 may be selected from alkoxy and/or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and an acyloxy group and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

For example, R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

The organometallic compound is one or more compounds selected from Group 1.

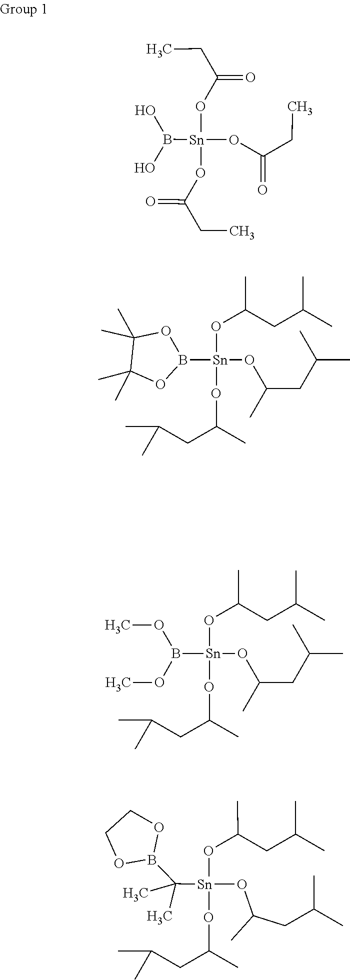

In a semiconductor photoresist composition according to some example embodiments, the organometallic compound may be included in an amount of about 0.5 wt % to about 30 wt %, for example, about 1 wt % to about 30 wt %, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt %, based on 100 wt % of the semiconductor photoresist composition, but is not limited thereto. If (e.g., when) the organometallic compound is included in the amount within the above ranges, the storage stability and etch resistance of the semiconductor photoresist composition are improved, and the resolution characteristics are improved.

According to some example embodiments, a semiconductor photoresist composition can further improve the sensitivity of the photoresist and pattern formation by including the organometallic compound within the above amount ranges.

The solvent included in the semiconductor photoresist composition according to some example embodiments may be an organic solvent, and may include, for example, an aromatic compound (e.g., xylene, and/or toluene), alcohol (e.g., 4-methyl-2-pentanol, 2-methyl-1-propanol, 1-butanol, methanol, isopropyl alcohol, and/or 1-propanol), ether (e.g., anisole, and/or tetrahydrofuran), ester (n-butyl acetate, propylene glycol monomethyl ether acetate, ethyl acetate, and/or ethyl lactate), ketone (e.g., methyl ethyl ketone, and/or 2-heptanone), or a mixture thereof, but is not limited thereto.

In some example embodiments, the semiconductor photoresist composition may further include a resin in addition to the aforementioned organometallic compound and solvent.

The resin may be a phenolic resin including at least one aromatic moiety listed in Group 2.

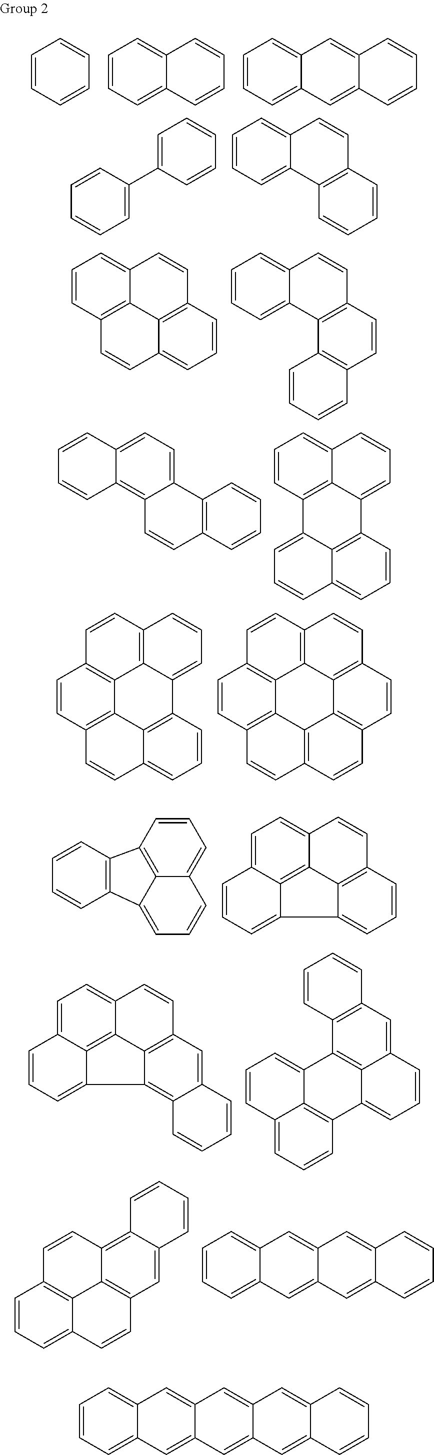

The resin may have a weight average molecular weight of about 500 g/mol to about 20,000 g/mol.

The resin may be included in an amount of about 0.1 wt % to about 50 wt % based on a total amount of the semiconductor photoresist composition. If the resin is included in the foregoing amount range, it may have excellent etch resistance and heat resistance.

It is desirable that the semiconductor photoresist composition, according to one or more embodiments, is composed of the above-described organometallic compound, solvent, and resin. The semiconductor photoresist composition according to the above-described embodiments may further include an additive, if necessary or desired. Examples of the above additive may include a surfactant, a crosslinking agent, a leveling agent, organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but is not limited thereto. The crosslinking agent may have at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used to improve coating flatness during printing and may be a suitable commercially available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl (p-tolyl) amine, methyl diphenyl amine, triphenyl amine, phenylenediamine, naphthylamine, diaminonaphthalene, or a combination thereof.

Each use amount of the additives may be controlled depending on suitable or desired properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(β-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but the present disclosure is not limited thereto.

The semiconductor photoresist composition may be formed into a pattern having a high aspect ratio without a collapse (e.g., without or substantially without collapse of the pattern). Accordingly, in order to form a fine pattern having a width of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength in a range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some example embodiments may be used to realize extreme ultraviolet lithography using an EUV light source that emits light having a wavelength of about 13.5 nm.

According to some example embodiments, a method of forming patterns using the aforementioned semiconductor photoresist composition is provided. For example, the manufactured pattern may be a photoresist pattern.

The method of forming patterns according to some example embodiments includes forming an etching-objective layer on a substrate, coating the semiconductor photoresist composition on the etching-objective layer to form a photoresist film, patterning the photoresist film to form a photoresist pattern, and etching the etching-objective layer using the photoresist pattern as an etching mask.

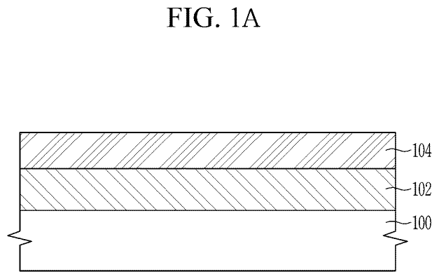

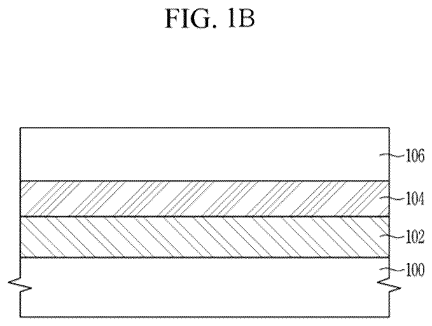

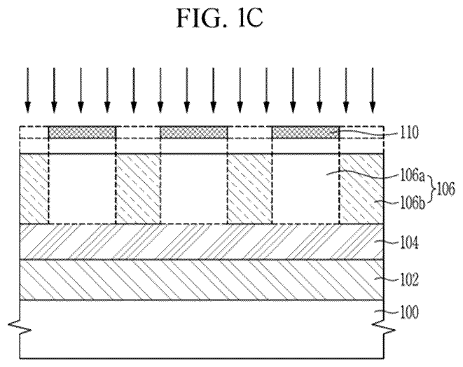

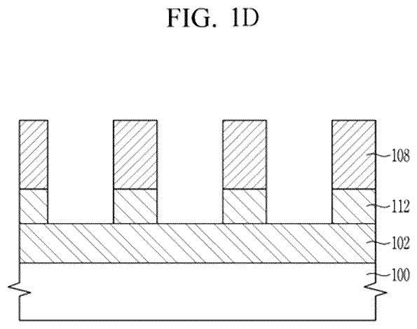

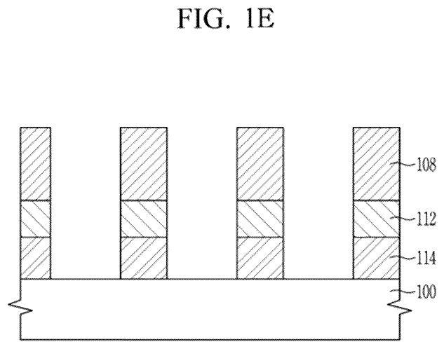

Hereinafter, a method of forming patterns using the semiconductor photoresist composition is described referring to FIGS. 1A to 1E. FIGS. 1A to 1E are cross-sectional views that show a method of forming patterns using a semiconductor photoresist composition according to some example embodiments.

Referring to FIG. 1A, an object for etching is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, the embodiments are not limited thereto, and various suitable coating methods, for example a spray coating, a dip coating, a knife edge coating, a printing method, for example an inkjet printing and a screen printing, and/or the like may be used.

The coating process of the resist underlayer may not be provided, and hereinafter, a process including a coating of the resist underlayer is described.

The coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist film 106 and thus may prevent or reduce non-uniformity and deteriorated pattern formability of a photoresist line width that would otherwise occur if (e.g., when) a ray reflected from on the interface between the substrate 100 and the photoresist film 106 or a hardmask between layers is scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

In one or more embodiments, the formation of a pattern by using the semiconductor photoresist composition may include coating the semiconductor resist composition on the substrate 100 having the thin film 102 through spin coating, slit coating, inkjet printing, and/or the like and then, drying it to form the photoresist film 106.

The semiconductor photoresist composition has already been illustrated in more detail and will not be illustrated again.

Subsequently, a substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation with light having a high energy and short wavelength such as EUV (extreme ultraviolet; a wavelength of about 13.5 nm), an E-Beam (an electron beam), and/or the like as well as light with a short wavelength such as an i-line (a wavelength of about 365 nm), a KrF excimer laser (a wavelength of about 248 nm), an ArF excimer laser (a wavelength of about 193 nm), and/or the like.

In one or more embodiments, light for the exposure may be light in a range from about 5 nm to about 150 nm and a high energy wavelength, for example, EUV (extreme ultraviolet; a wavelength of 13.5 nm), an E-Beam (an electron beam), and/or the like.

The exposed region 106b of the photoresist film 106 has a different solubility from the unexposed region 106a of the photoresist film 106 by forming a polymer by a crosslinking reaction such as a condensation reaction between organometallic compounds.

Subsequently, the substrate 100 is subjected to a second baking process. The second baking process may be performed at a temperature of about 90° C. to about 200° C. The exposed region 106b of the photoresist film 106 becomes easily indissoluble by a developer due to the second baking process (e.g., the exposed region 106b cannot be dissolved by the developing solution after the second baking process).

In FIG. 1D, the unexposed region 106a of the photoresist film is dissolved and removed using the developer to form a photoresist pattern 108. In one or more embodiments, the unexposed region 106a of the photoresist film is dissolved and removed by using an organic solvent such as 2-heptanone and/or the like to complete the photoresist pattern 108 corresponding to the negative tone image.

As described above, a developer used in a method of forming patterns according to some example embodiments may be an organic solvent. The organic solvent used in the method of forming patterns according to some example embodiments may be for example ketones such as methylethylketone, acetone, cyclohexanone, 2-heptanone, and/or the like, alcohols such as 2-methyl-1-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some example embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like as well as light having a short wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern 108 may have a pitch of having a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

Next, the resist underlayer 104 is etched using the photoresist pattern 108 as an etching mask. Through this etching process, an organic film pattern 112 is formed. The organic film pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be performed by dry etching using, for example, an etching gas, and the etching gas may be, for example, CHF₃, CF₄, Cl₂, BCl₃, and/or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of about 5 nm to about 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width of less than or equal to about 20 nm, like that of the photoresist pattern 108.

A method of forming a semiconductor photoresist pattern according to an embodiment may be performed such that an increase rate of a pattern line width (CD, Critical Dimension) formed under a condition including nitrogen oxide (NOx), relative to a pattern line width formed under a condition not including nitrogen oxide, is less than 10%. For example, the pattern line width increase rate may be less than 10%, less than 9.9%, less than 9.8%, less than 9.7%, less than 9.6%, or less than 9.5%. In the above, the condition not including nitrogen oxide refers to a condition controlled such that nitrogen oxide is substantially non-existent or exists at a technically negligible concentration (e.g., less than 1 ppb). In addition, the condition including nitrogen oxide refers to a condition in which nitrogen oxide is present in the atmosphere, and for example, refers to a condition in which nitrogen oxide is included at a concentration of 0.001 ppm to 1.0 ppm.

The concentration condition of the nitrogen oxide may be adjusted as necessary within a range of 0.001 ppm to 1.0 ppm, and in an embodiment of the present disclosure, the condition including nitrogen oxide may refer to a concentration of 0.1 ppm.

The line width increase rate may be measured by comparing respective pattern line widths formed under the same process conditions except for the presence or absence of nitrogen oxide. Regarding the semiconductor photoresist composition according to an embodiment, even if (e.g., when) nitrogen oxide is present in the atmosphere during a pattern forming process, a side reaction between an organometallic compound in the composition and the nitrogen oxide may be suppressed, thereby minimizing unnecessary line width increase and pattern defects and enabling formation of a precise pattern.

A pattern formed using the semiconductor photoresist composition according to an embodiment may have a rate of increase in pattern line width formed under a condition including nitrogen oxide, relative to a pattern line width formed under a condition not including nitrogen oxide, that is less than 10%.

Hereinafter, embodiments of the present disclosure will be described in more detail through examples of the preparation of the aforementioned semiconductor photoresist composition. However, the present disclosure is technically not restricted by the following examples.

### Synthesis of Organometallic Compound

### Synthesis Example 1

### Synthesis Method of Chemical Formula A

5 g of PhSn[(C₆H₄)PPh₂] and 5 g of B(OH)₂Br·SMe₂ were dissolved in 50 mL of anhydrous benzene and then, stirred at room temperature (23±2° C.) for 3 hours. When a reaction was completed, after removing the solvent, the residue was 3 times washed with n-hexane to obtain a yellow solid. 6 g of the yellow solid was added to 300 g of propionic acid and then, heated under reflux for 24 hours. Unreacted propionic acid was removed under a reduced pressure, obtaining a compound represented by Chemical Formula A-1.

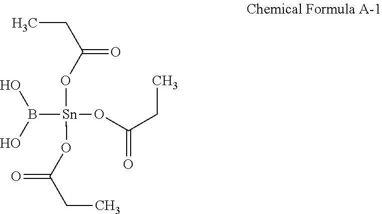 [SMILES: CCC(=O)[O][Sn]([O]C(=O)CC)([O]C(=O)CC)[B](O)O]

### Synthesis Example 2

5 g of PhSn[(C₆H₄)PPh₂] and 5 g of B(OMe)₂Br·SMe₂ were added to 50 mL of anhydrous benzene and then, stirred at room temperature (23±2° C.) for 3 hours. When a reaction was completed, after removing the solvent, the residue was 3 times washed with n-Hexane to obtain a yellow solid. Subsequently, 50 mL of anhydrous pentane was added to 6 g of the yellow solid, and 20 g of methyl isobutyl carbinol (MIBC) was added thereto, while maintaining 0° C., and then, stirred at room temperature (23±2° C.) for 6 hours. When a reaction was completed, the resultant was filtered, concentrated, and vacuum-dried, obtaining a compound represented by Chemical Formula A-2.

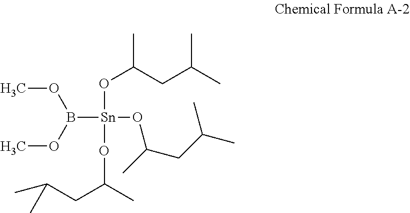 [SMILES: CO[B](OC)[Sn]([O]C(C)CC(C)C)([O]C(C)CC(C)C)[O]C(C)CC(C)C]

### Synthesis Example 3

A compound represented by Chemical Formula A-3 was obtained in substantially the same manner as in Synthesis Example 2 except that XBr·SMe₂

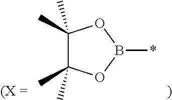

was used instead of the B(OMe)₂Br·SMe₂.

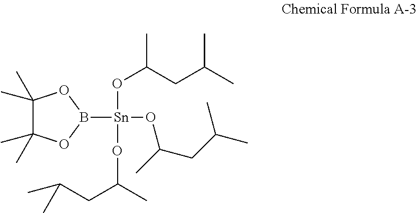 [SMILES: CC(C)CC(C)[O][Sn]([O]C(C)CC(C)C)([O]C(C)CC(C)C)[B]1OC(C)(C)C(C)(C)O1]

### Synthesis Example 4

A compound represented by Chemical Formula A-4 was obtained in substantially the same manner as in Synthesis Example 2 except that B(C₂H₄O₂)Br·SMe₂ was used instead of the B(OMe)₂Br·SMe₂.

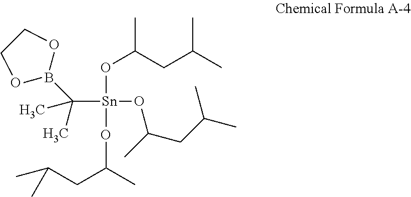 [SMILES: CC(C)CC(C)[O][Sn]([O]C(C)CC(C)C)([O]C(C)CC(C)C)[C](C)(C)B1OCCO1]

### Comparative Synthesis Example 1

40.7 g of t-ButylSnPh3 and 300 g of propionic acid were added to a 250 mL 2-neck round-bottomed flask and then, heated under reflux for 24 hours. Unreacted propionic acid was removed under a reduced pressure, obtaining a compound represented by Chemical Formula B-1.

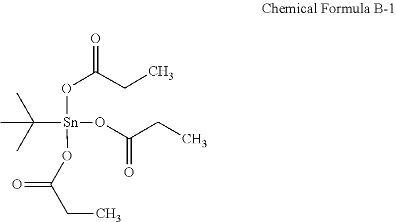 [SMILES: CCC(=O)[O][Sn]([O]C(=O)CC)([O]C(=O)CC)[C](C)(C)C]

### Comparative Synthesis Example 2

A compound represented by Chemical Formula B-2 was obtained in substantially the same manner as in Comparative Synthesis Example 1 except that t-AmylSnPh₃ was used instead of the t-ButylSnPh₃.

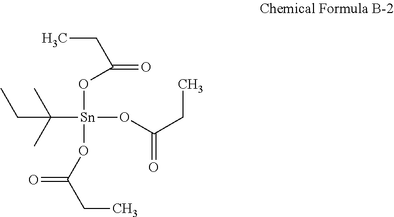 [SMILES: CCC(=O)[O][Sn]([O]C(=O)CC)([O]C(=O)CC)[C](C)(C)CC]

### Comparative Synthesis Example 3

10 g of t-butylSn(dimethylamine)₃ and 50 ml of anhydrous pentane were added to a 250 mL round-bottomed flask, and 20 g of MIBC was added thereto, while maintaining 0° C., and then, stirred at room temperature (23±2° C.) for 6 hours. When a reaction was completed, the resultant was filtered, concentrated, and vacuum-dried, obtaining a compound represented by Chemical Formula B-3.

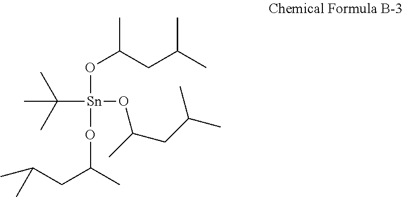 [SMILES: CC(C)CC(C)[O][Sn]([O]C(C)CC(C)C)([O]C(C)CC(C)C)[C](C)(C)C]

### Comparative Synthesis Example 4

A compound represented by Chemical Formula B-4 was obtained in substantially the same manner as in Comparative Synthesis Example 3 except that t-amylSn(dimethylamine)₃ was used instead of the t-butylSn(dimethylamine)₃.

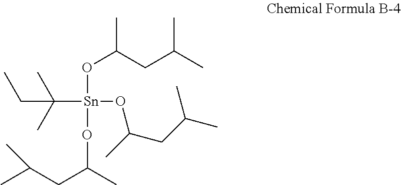 [SMILES: CC[C](C)(C)[Sn]([O]C(C)CC(C)C)([O]C(C)CC(C)C)[O]C(C)CC(C)C]

### Preparation of Semiconductor Photoresist Compositions

### Examples 1 to 4 and Comparative Examples 1 to 4

The organometallic compounds according to Synthesis Examples 1 to 4 and Comparative Synthesis Examples 1 to 4 were respectively dissolved in PGMEA (propylene glycol monomethyl ether acetate) at a concentration of 3 wt % and then, filtered with a 0.1 μm PTFE syringe filter to prepare semiconductor photoresist compositions of the examples and the comparative examples.

### Evaluation of Scum Occurrence

The semiconductor photoresist compositions were respectively coated to be 240 Å thick on a silicon wafer and then, proceeded with PAB, exposure, PEB, and development to form films with patterns.

The photoresist compositions of the examples and the comparative examples were respectively spin-coated on a 200 mm circular silicon wafer deposited with HMDS on the surface at 1500 rpm for 30 seconds and then, baked (post-apply baked, PAB) at 110° C. for 60 seconds and allowed to stand at room temperature (23±2° C.) for 30 seconds. Subsequently, a linear array with a width of 50 nm was projected onto the wafer by using EUV light (Lawrence Berkeley National Laboratory Micro Exposure Tool, MET). Herein, exposure time of the pads was adjusted to apply the EUV light in an increase dose to each of the pads.

Subsequently, the resist and the substrate were exposed at 170° C. for 60 seconds on the hot plate and then, baked. The baked film was developed in a PGMEA solvent to form a negative tone image. Finally, the process was completed by performing hot plate-baking at 150° C. for 60 seconds.

The formed patterns were measured with respect to line width and LER (line edge roughness, unit: nm) by using SEM (Scanning electron microscopy) to check whether or not scums occurred, and the results are shown in Table 1.

In one or more embodiments, with reference to Comparative Example 1, a concentration of nitrogen oxide (NOx) which caused 15% of critical dimension (CD) at the same exposure dose was determined to define a high-concentration NOx environment (about 0.1 ppm), and then, each photoresist with patterns was exposed to the high concentration NOx environment and no NOx environment to measure changes in CD. The changes in CD under the high concentration NOx environment and no NOx environment were used to evaluate improvement degrees due to NOx impact according to the following criteria, and the results are shown in Table 1. NOx impact improvement evaluation criteria

TABLE 1
○: less than 5%
Δ: 5% or more but less than 10%
X: 10% or more

| | | | | NOx |
|---|---|---|---|---|
| | | | Scum | impact |
| | organometallic | LER | occurs | improve- |
| | compound | (nm) | or not | ment |
| Example 1 | Chemical | 3.1 | X | Δ |
| | Formula A-1 | | | |
| Example 2 | Chemical | 3.8 | X | ○ |
| | Formula A-2 | | | |
| Example 3 | Chemical | 3.7 | X | ○ |
| | Formula A-3 | | | |
| Example 4 | Chemical | 4.3 | X | ○ |
| | Formula A-4 | | | |
| Comparative | Chemical | 6.4 | ○ | X |
| Example 1 | Formula B-1 | | | |
| Comparative | Chemical | 7.1 | ○ | X |
| Example 2 | Formula B-2 | | | |
| Comparative | Chemical | 8.1 | X | Δ |
| Example 3 | Formula B-3 | | | |
| Comparative | Chemical | 8.5 | ○ | Δ |
| Example 4 | Formula B-4 | | | |

Referring to Table 1, the patterns formed by respectively using the semiconductor photoresist compositions according to Examples 1 to 4, compared those formed by respectively using the semiconductor photoresist compositions according to Comparative Examples 1 to 4, were confirmed to exhibit small LER and small changes in CD due to the different NOx environments. The patterns according to the examples exhibited no scums, but the patterns of the comparative examples 1, 2, and 4 exhibited scums. The semiconductor photoresist composition according to some example embodiments exhibited excellent pattern-forming capability and reduced defects or residues in the patterns, which confirmed to be less affected by nitrogen oxide in the air.

Hereinbefore, certain embodiments have been described and illustrated, however, it should be apparent to a person having ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Description of Symbols

100: substrate
102: thin film
104: resist underlayer
106: photoresist film
106a: unexposed region
106b: exposed region
108: photoresist pattern
112: organic film pattern
110: patterned mask
114: thin film pattern

What is claimed is:

1. A semiconductor photoresist composition, comprising:
an organometallic compound represented by Chemical Formula 1; and a solvent: 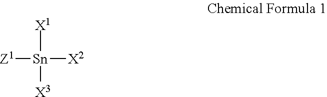
wherein, in Chemical Formula 1,
Z¹ is a group containing at least one boron,
X¹ to X³ are each independently alkoxy or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an acyloxy group and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylamido or dialkylamido (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidato (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), amidinato (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), alkylthio or arylthio (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

2. The semiconductor photoresist composition as claimed in claim 1, wherein in Chemical Formula 1, Z¹ is a group represented by Chemical Formula 2: 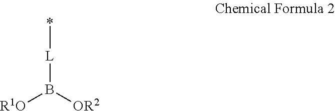
wherein, in Chemical Formula 2,
L is a single bond, or a substituted or unsubstituted C1 to C10 alkylene group,
R¹ and R² are each independently hydrogen, deuterium, halogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C20 aryl group, or R¹ and R² are optionally linked to form a ring, and
* is a linking point with Sn of Chemical Formula 1.

3. The semiconductor photoresist composition as claimed in claim 2, wherein in Chemical Formula 2, R¹ and R² are each independently hydrogen, a substituted or unsubstituted C1 to C20 alkyl group, or a substituted or unsubstituted C2 to C20 alkenyl group, or R¹ and R² are optionally linked to form a ring.

4. The semiconductor photoresist composition as claimed in claim 2, wherein in Chemical Formula 2, R¹ and R² are optionally linked to form a substituted or unsubstituted C2 to C20 heterocycle.

5. The semiconductor photoresist composition as claimed in claim 1, wherein R^{b} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
R^{c}, R^{d}, R^{e}, R^{f}, R^{g}, R^{h}, Rⁱ, R^{j}, R^{k}, and R^{l} are each independently hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

6. The semiconductor photoresist composition as claimed in claim 1, wherein in Chemical Formula 1, at least one of X¹, X², or X³ is selected from alkoxy or aryloxy (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and an acyloxy group and a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

7. The semiconductor photoresist composition as claimed in claim 6, wherein R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

8. The semiconductor photoresist composition as claimed in claim 1, wherein the organometallic compound is one or more compounds selected from Group 1:

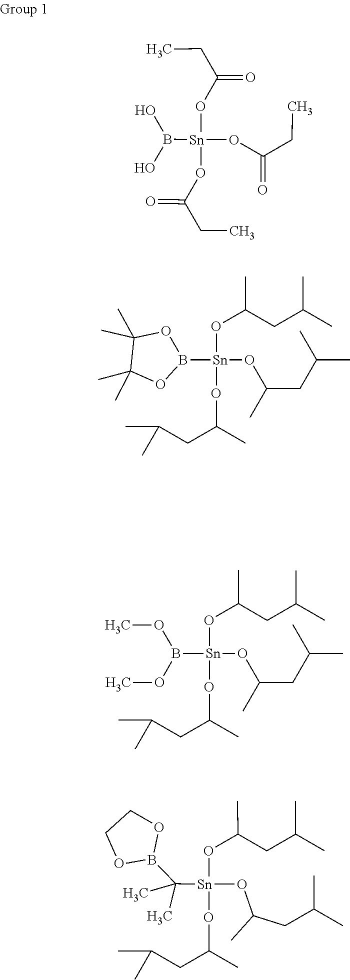

9. The semiconductor photoresist composition as claimed in claim 1, wherein the organometallic compound is included in an amount of 0.5 wt % to 30 wt % based on 100 wt % of the semiconductor photoresist composition.

10. The semiconductor photoresist composition as claimed in claim 1, wherein the composition further comprises an additive of a surfactant, a crosslinking agent, a leveling agent, an organic acid, an inhibitor, or a combination thereof.

11. A method of forming patterns, comprising:
forming an etching-objective layer on a substrate;
coating the semiconductor photoresist composition as claimed in claim 1 on the etching-objective layer to form a photoresist film;
patterning the photoresist film to form a photoresist pattern; and
etching the etching-objective layer using the photoresist pattern as an etching mask.

12. The method as claimed in claim 11,
wherein the patterning of the photoresist film to form the photoresist pattern is performed such that an increase rate of a line width of the photoresist pattern formed under a condition including nitrogen oxide at a concentration of 0.1 ppm relative to a line width of the photoresist pattern formed under a condition not including nitrogen oxide is less than 10%.
